(19) United States
(12) Patent Application Publication
(10) Pub. No.: US 2024/0154035 A1
(43) Pub. Date: May 9, 2024

(54) SEMICONDUCTOR APPARATUS AND FORMING METHOD FOR FERROELECTRIC THIN FILM

(71) Applicant: TOKYO INSTITUTE OF TECHNOLOGY, Tokyo (JP)

(72) Inventor: Shun-ichiro OHMI, Tokyo (JP)

(21) Appl. No.: 18/281,445

(22) PCT Filed: Feb. 18, 2022
(86) PCT No.: PCT/JP2022/006613

§ 371 Date: Sep. 11, 2023

(30) Foreign Application Priority Data
Mar. 11, 2021 (JP) 2021-039611

(51) Int. Cl. H01L 29/78; H01L 21/28; H01L 29/51; H10B 51/30

(52) U.S. Cl. CPC H01L 29/78391; H01L 29/40111; H01L 29/516; H10B 51/30

(57) ABSTRACT

A semiconductor apparatus includes an Si substrate and a ferroelectric thin film. The ferroelectric thin film is formed on the Si substrate. The ferroelectric thin film includes HfNₓ (1<x) having a rhombohedral crystal structure.

### CROSS REFERENCE TO RELATED APPLICATIONS

This is the U.S. national stage of application No. PCT/JP2022/006613, filed on Feb. 18, 2022. Priority under 35 U.S.C. § 119(a) and 35 U.S.C. § 365(b) is claimed from Japanese Application No. 2021-039611, filed Mar. 11, 2021, the disclosure of which is also incorporated herein by reference.

### BACKGROUND

### 1. Technical Field

The present invention relates to a ferroelectric thin film.

### 2. Description of the Related Art

In recent years, accompanying improvement of the performance and power consumption of portable information communication devices, it has become an important issue to provide nonvolatile memory to be employed as semiconductor memory in a semiconductor circuit with larger capacitance, higher operating speed, and lower power consumption. Typical examples of such nonvolatile memory include flash memory.

Ferroelectric hafnium oxide (Fe-Hfo₂) is a metastable-phase orthorhombic crystal, and ferroelectricity can be obtained even in a case in which the ferroelectric hafnium oxide is provided in the form of a very thin film on the order of 10 nm. Accordingly, research on Metal-Ferroelectric-Semiconductor Field-Effect Transistors (MFSFETs) employing ferroelectric HfO₂ has been advancing in order to provide miniaturized MSFETs and a highly integrated circuit thereof (Non-patent document 1). Research on integrated circuits configured to emulate the operation of the human brain using MFSFETs as analog memory has been actively advancing (Non-patent document 2).

In order to provide such an application of analog memory, it is important to control a threshold voltage (Vth) with high precision. At present, in most reports, HfO₂ is doped with zirconium (Zr), silicon (Si), or the like, so as to form ferroelectric HfO₂. This leads to variation of the threshold voltage due to dopant distribution, which is a problem.

The present inventor has formed non-doped HfO₂ having a film thickness of 10 nm on a Si substrate such that it exhibits ferroelectricity, so as to provide MFSFET operation with a power supply voltage of 2.5 V (Patent document 3).

### DOCUMENT LIST

Non-patent document 1
S. Böscke et al., IEDM Tech. Dig., 547 (2011).
Non-patent document 2
S. Dutta et al., VLSI Symp. Tech.Dig., T-38 (2019).
Non-patent document 3
S. Ohmi et al., Device Research Conference, 96 (2020).
Non-patent document 4
S. Ohmi et al., Device Research Conference, 181 (2019).
Non-patent document 5
C. Hu et. al., Scripta Materialia 108, pp. 141-146 (2015).
Non-patent document 6
S. Ohmi et at., IEEE Trans. Electron Devices (2021) [in press].

In a case in which such HfO₂ is formed on a Si substrate, such formation requires high-temperature processing. This leads to the formation of a SiO₂ layer having a low dielectric constant at an interface between the Si substrate and the HfO₂. The SiO₂ layer generates an electric field (depolarizing electric field) in the opposite direction to the electric field generated by the HfO₂ layer. This becomes a factor that causes degradation of memory characteristics.

### SUMMARY

The present disclosure has been made in view of such a situation. Accordingly, it is an exemplary purpose of an embodiment to provide a ferroelectric thin film without a layer having a low dielectric constant at the interface between it and a Si substrate and a semiconductor apparatus employing such a ferroelectric thin film.

A semiconductor apparatus according to an embodiment of the present disclosure includes a Si substrate and a ferroelectric thin film formed on the Si substrate and including HfNₓ (1<x) having a rhombohedral crystal structure.

Another embodiment of the present disclosure relates to a forming method for a ferroelectric thin film. The forming method includes: forming a HfNₓ (1<x) layer by depositing Hf on a Si substrate using an Electron Cyclotron Resonance (ECR) sputtering method in a gas atmosphere including N₂ and Ar; crystalizing the HfNₓ layer into a rhombohedral crystal structure by subjecting it to heat treatment after it is formed.

Yet another embodiment of the present disclosure relates to a semiconductor apparatus. The semiconductor apparatus includes a transistor. The transistor includes: a Si substrate; a ferroelectric thin film formed in a gate region on the Si substrate, and including HfNₓ (1<x) having a rhombohedral crystal structure; and n⁺ layers formed in a drain region and a source region each adjacent to the gate region on the Si substrate.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional diagram showing a basic configuration of a semiconductor apparatus according to an embodiment;

FIG. 2 is a diagram showing the crystal structure of HfNₓ;

FIG. 3 is a cross-sectional diagram of a semiconductor apparatus according to an example;

FIG. 4 is a cross-sectional diagram of a semiconductor apparatus according to an example;

FIGS. 5A, 5B, 5C, 5D, 5E, and 5F are diagrams for explaining a manufacturing method of the semiconductor apparatus shown in FIG. 4;

FIG. 6 is a diagram showing the relation between the gas flow ratio in the deposition of HfNₓ and the composition ratio of Hf and N;

FIG. 7 is a diagram showing measurement results of a manufactured sample measured using the X-ray diffraction (XRD) method;

FIG. 8 is a diagram showing the P-V (polarization-voltage) characteristics of a MFS diode sample;

FIG. 9 is a diagram showing the C-V (capacitance-voltage) characteristics of a MFS diode sample;

FIG. 10A and FIG. 10B are diagrams each showing the measurement results of the fatigue characteristics of the MFS diode sample;

FIG. 11 is a cross-sectional diagram of a semiconductor apparatus according to an example; and

FIG. 12 is a cross-sectional diagram of a semiconductor apparatus according to an example.

### DETAILED DESCRIPTION

### Outline of Embodiments

Description will be made regarding the outline of several exemplary embodiments of the present disclosure. The outline is a simplified explanation regarding several concepts of one or multiple embodiments as a preface to the detailed description described later in order to provide a basic understanding of the embodiments. That is to say, the outline described below is by no means intended to restrict the scope of the present invention and the present disclosure. Furthermore, the outline described below is by no means a comprehensive outline of all possible embodiments. That is to say, the outline is by no means intended to identify the indispensable elements of the embodiments. For convenience, in some cases, an “embodiment” as used in the present specification represents a single or multiple embodiments (examples and modifications) disclosed in the present specification.

The outline is not meant to be an extensive outline of all conceivable embodiments. Furthermore, the outline is not intended to identify essential elements of all the embodiments or specific essential elements, nor to define the scope of part of or all the embodiments. The sole purpose of the outline is to propose several concepts of one or multiple embodiments in a simplified form as a prelude to the more detailed description that is presented later.

Conventionally, there has been research on hafnium nitride (HfN) directing attention to its characteristics as a high-k insulating material. However, such research has mainly been conducted for amorphous HfN (Non-patent document 4).

Also, Non-patent document 5 reports that HfNₓ has a different crystal structure according to the composition ratio x of N with respect to Hf Specifically, Non-patent document 5 reports that HfN_{1.165} has a rhombohedral crystal structure. However, there has been no report that HfN exhibits ferroelectricity.

The present inventor has focused on the asymmetric structure of the rhombohedral crystal system of HfNₓ. The present inventor has acquired the idea that such an asymmetric structure has the potential to provide a HfNₓ thin film having ferroelectricity.

A semiconductor apparatus according to one embodiment includes a Si substrate and a ferroelectric thin film formed on the Si substrate and including HfNₓ (1<x) having a rhombohedral crystal structure.

With such an arrangement in which the ratio x of N in HfNₓ is larger than 1, this is capable of providing the crystal structure of HfNₓ with asymmetry, thereby enabling the provision of ferroelectricity. The manufacturing process of the semiconductor apparatus requires no oxygen (O), which is required for the formation of HfO₂. Instead, N is used. Accordingly, no SiO₂ layer is formed as an interface between the ferroelectric thin film and the Si substrate. Furthermore, the nitridation rate of Si is small as compared with the oxidation rate thereof. Moreover, the energy required for a reaction is larger with N than with O. Accordingly, even in a case in which the semiconductor apparatus is subjected to heat treatment, a SiN layer having a low dielectric constant does not readily occur as an interface between HfNₓ and Si, thereby providing a high-quality ferroelectric thin film.

With this, as x becomes closer to 1, the HfNₓ readily becomes a metallic crystal structure. In contrast, as x becomes closer to 1.33, the HfNₓ readily becomes an insulating stable-phase crystal structure. Therefore, in one embodiment, an arrangement may be made in which 1.1≤x≤1.3 holds true. More preferably, an arrangement may be made in which 1.15≤x≤1.2 holds true.

In one embodiment, the semiconductor apparatus may further include an SiO₂ layer formed outside an active region in which the semiconductor device is formed. With such an arrangement including the SiO₂ layer, this is capable of suppressing the occurrence of leakage from a side face of the device, thereby providing improved device characteristics.

In one embodiment, the semiconductor apparatus may include: a contact layer including HfN_{y} (y<1) formed on the ferroelectric thin film; and a metal electrode formed on the contact layer. In this example, as y becomes closer to 0, the HfN_{y} is readily oxidized. In contrast, as y becomes closer to 1, the resistance of the HfN_{y} becomes higher. Accordingly, y is preferably designed to be 0.3≤y≤0.8.

In one embodiment, the ferroelectric thin film may have a thickness of 3 nm to 20 nm.

A forming method for a ferroelectric thin film according to one embodiment includes: forming a HfNₓ (1<x) layer by depositing Hf on a Si substrate using an Electron Cyclotron Resonance (ECR) sputtering method in a gas atmosphere including N₂ and Ar; crystalizing the HfNₓ layer into a rhombohedral crystal structure by subjecting it to heat treatment after it is formed.

A semiconductor apparatus according to one embodiment includes a transistor. The transistor includes: a Si substrate; a ferroelectric thin film formed in a gate region on the Si substrate, and including HfNₓ (1<x) having a rhombohedral crystal structure; and n⁺ layers formed in a drain region and a source region each adjacent to the gate region on the Si substrate.

With such an arrangement in which the ratio x of N in HfNₓ is larger than 1, this is capable of providing the crystal structure of HfNₓ with asymmetry, thereby enabling the provision of ferroelectricity. With such an arrangement in which the insulating layer of HfNₓ is used as a gate insulating film, this prevents the formation of a layer having a low dielectric constant between the gate insulating film and the Si substrate. This provides a high-performance ferroelectric gate transistor (MFSFET: Metal-Ferroelectric-Semiconductor Field-Effect Transistor). In a case in which such a MFSFET is employed as a memory storage element, this reduces the effect of a depolarizing electric field as compared with the MFSFET employing an HfO₂ ferroelectric thin film as a gate insulating film, thereby providing improved memory characteristics.

In one embodiment, an arrangement may be made in which 1.1≤x≤1.3 holds true. More preferably, an arrangement may be made in which 1.15≤x≤1.2 holds true.

In one embodiment, the semiconductor apparatus may further include a SiO₂ layer formed on the Si substrate such that it is formed outside an active region including the gate region, the source region, and the drain region. This is capable of suppressing the occurrence of leakage from a side face of the device, thereby providing improved device characteristics.

### Embodiments

Description will be made below regarding the preferred embodiments with reference to the drawings. The same or similar components, members, and processes are denoted by the same reference numerals, and redundant description thereof will be omitted as appropriate. The embodiments have been described for exemplary purposes only, and are by no means intended to restrict the present disclosure or the present invention. Also, it is not necessarily essential for the present invention that all the features or a combination thereof be provided as described in the embodiments.

In the present specification, the state represented by the phrase “the member A is coupled to the member B” includes a state in which the member A is indirectly coupled to the member B via another member that does not substantially affect the electric connection between them, or that does not damage the functions or effects of the connection between them, in addition to a state in which they are physically and directly coupled.

Similarly, the state represented by the phrase “the member C is provided between the member A and the member B” includes a state in which the member A is indirectly coupled to the member C, or the member B is indirectly coupled to the member C via another member that does not substantially affect the electric connection between them, or that does not damage the functions or effects of the connection between them, in addition to a state in which they are directly coupled.

It should be noted that the scale of the components shown in the drawings is expanded or reduced as appropriate for ease of understanding.

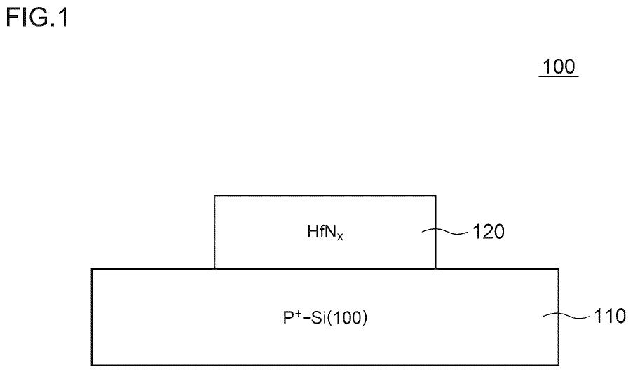

FIG. 1 is a cross-sectional diagram showing a basic configuration of a semiconductor apparatus 100A according to an embodiment. The semiconductor apparatus 100A includes a Si substrate 110 and a ferroelectric thin film 120. For example, as the Si substrate 110, a P⁺-Si(100) substrate or a p-Si(100) substrate may be employed.

The ferroelectric thin film 120 is formed on the Si substrate 110 and includes HfNₓ (1<x). The composition ratio x is in a range of 1.1≤x≤1.3. Preferably, the composition ratio x is in a range of 1.15≤x≤1.2. Furthermore, the ferroelectric thin film 120 may be designed to have a thickness of 3 nm to 20 nm. For example, the ferroelectric thin film 120 may be designed to have a thickness of 10 nm.

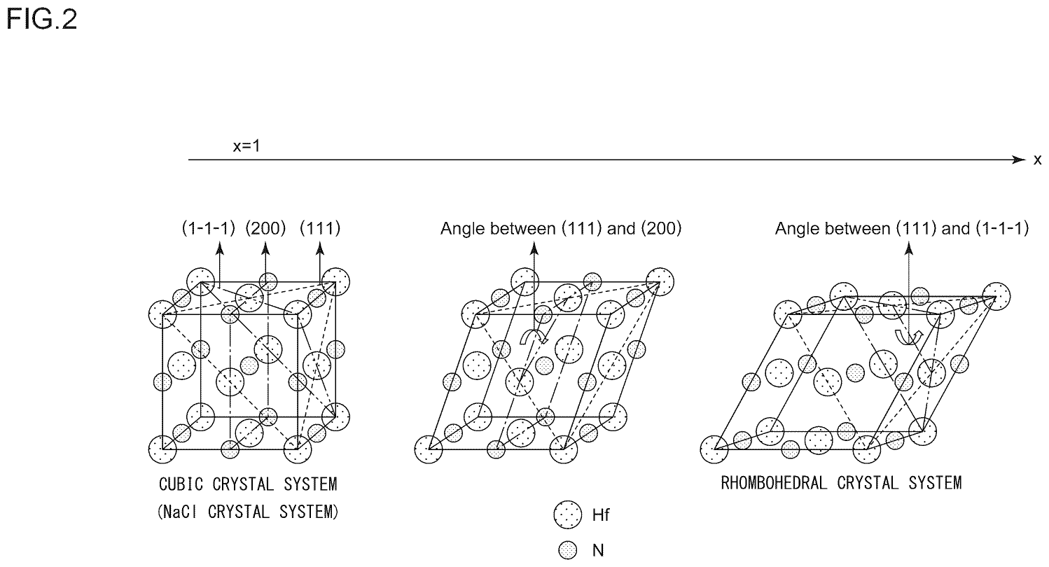

FIG. 2 is a diagram showing a crystal structure of HfNₓ. In a case in which x=1, HfNₓ has a cubic crystal structure. However, HfNₓ has a crystal structure that tilts according to an increase of the composition ratio x. Eventually, HfNₓ has a rhombohedral crystal structure. It should be noted that the crystal structure of the ferroelectric thin film 120 is not determined only by the composition ratio x, but also by a combination of the composition ratio x and the heat treatment conditions. In the present embodiment, the ferroelectric thin film 120 has a rhombohedral crystal structure. Accordingly, the combination of the composition ratio x and the heat treatment conditions in the manufacturing process may preferably be determined to provide an asymmetric rhombohedral crystal structure.

The above is the basic configuration of the semiconductor apparatus 100. The multilayer structure of the Si substrate 110 and the ferroelectric thin film 120 is a ferroelectric material/semiconductor multilayer structure. Furthermore, if a metal electrode is formed on the ferroelectric material/semiconductor multilayer structure, it becomes a MFS structure. It can be clearly understood by those skilled in this art that various kinds of semiconductor apparatuses such as diodes, transistors, etc., can be formed based on the basic structure shown in FIG. 1.

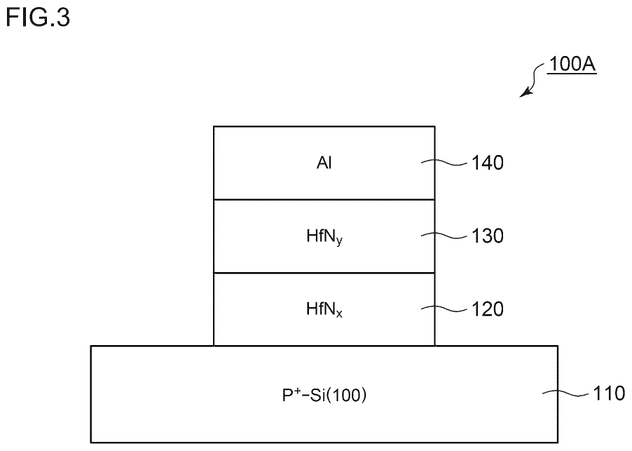

FIG. 3 is a cross-sectional diagram showing the semiconductor apparatus 100A according to an embodiment. The semiconductor apparatus 100A has a MFS structure including a Si substrate 110, a ferroelectric thin film 120, a contact layer 130, and a metal electrode 140.

The contact layer 130 includes HfN_{y} (y<1) and is formed on the ferroelectric thin film 120. The metal electrode 140 is formed of a metal material such as Al or the like and is formed on the contact layer 130. In addition to Al, examples of materials that can be employed as the metal electrode 140 include polycrystalline Si, TiN, W, Pt, etc. The thickness of the ferroelectric thin film 120 may be designed to be 3 nm to 20 nm, e.g., to be 10 nm. Furthermore, the thickness of the contact layer may be designed to be 10 nm to 30 nm, e.g., to be 20 nm.

A MFS diode can be formed by additionally forming an electrode on the Si substrate 110 side of the MFS structure. Furthermore, by forming a drain and a source in the Si substrate 110, this allows a transistor to be formed with the metal electrode 140 as a gate.

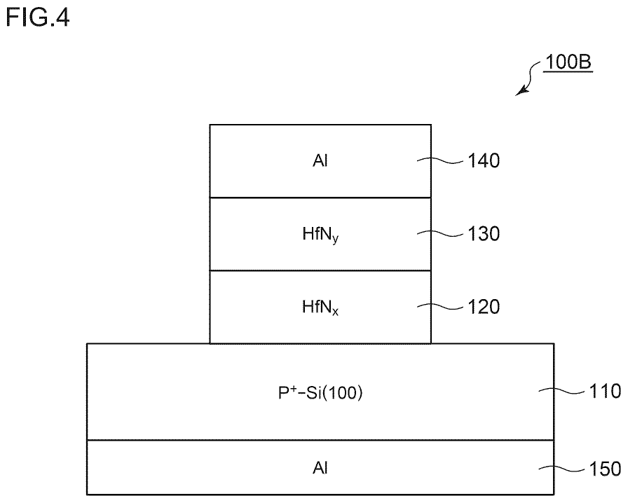

FIG. 4 is a cross-sectional diagram of a semiconductor apparatus 100B according to an embodiment. The semiconductor apparatus 100B is configured as a MFS diode. In addition to the MFS structure shown in FIG. 3, the semiconductor apparatus 100B includes a back-face electrode 150. As with the metal electrode 140, the back-face electrode 150 may be configured with a metal material such as Al or the like.

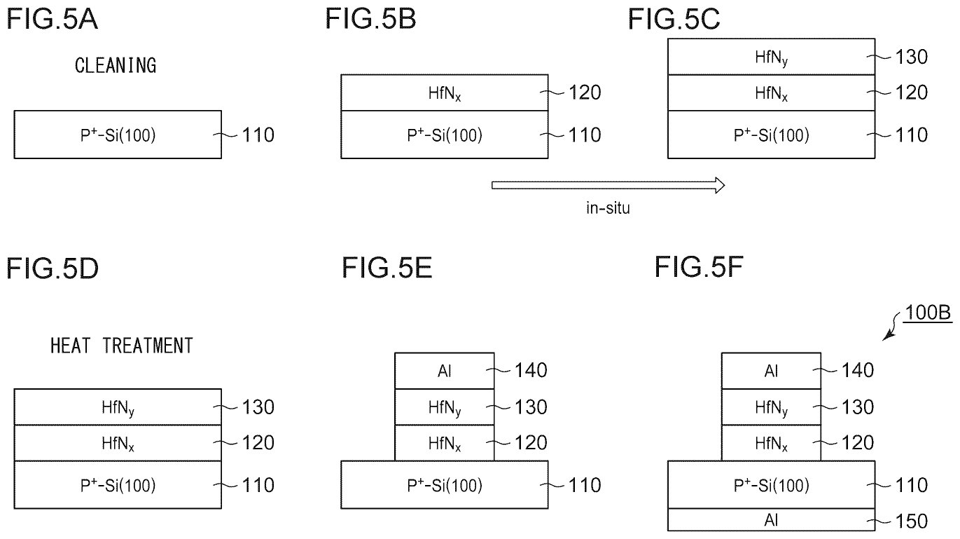

Next, description will be made regarding a manufacturing method for the ferroelectric thin film 120 and a manufacturing method for the semiconductor apparatus 100. FIGS. 5A through 5F are diagrams for explaining the manufacturing method for the semiconductor apparatus 100B shown in FIG. 4. As shown in FIG. 5A, the Si substrate 110 is chemically cleaned. The cleaning may be provided using a combination of sulfuric acid/hydrogen peroxide (SPM) cleaning and dilute hydrofluoric acid (DHF) cleaning.

Subsequently, as shown in FIG. 5B, the ferroelectric thin film 120 of HfNₓ (x>1) is formed on the Si substrate 110.

Subsequently, as shown in FIG. 5C, the contact layer 130 of HfNₓ (x<1) is formed on the ferroelectric thin film 120.

The ferroelectric thin film 120 and the contact layer 130 shown in FIGS. 5B and 5C can be formed in situ by sputtering at room temperature. As such sputtering, ECR sputtering can be employed. By switching the atmosphere gas (N₂ gas concentration), this is capable of forming HfNₓ and HfN_{y}.

Subsequently, as shown in FIG. 5D, heat treatment is applied so as to crystalize the HfNₓ in the ferroelectric thin film 120 into a rhombohedral crystal structure. As the heat treatment, Post-Metallization-Annealing (PMA) may be employed. Also, Post-Deposition Annealing (PDA) may be employed.

Subsequently, as shown in FIG. 5E, the metal electrode 140 is formed on the contact layer 130 by thermal evaporation or the like. The metal electrode 140 is patterned by dry etching as necessary. Subsequently, as shown in FIG. 5F, the back-face electrode 150 is formed on the back face of the Si substrate 110. As the material of the back-face electrode 150, as with the metal electrode 140, Al is preferably employed. Also, polycrystalline Si, TiN, W, Pt, or the like, may be employed.

The above is an example of the manufacturing method for the semiconductor apparatus 100B. It can be clearly understood by those skilled in this art that modifications may be made for each process, and that the order of several processes may be interchanged. With the manufacturing method using an in-situ process, by switching the atmosphere gas, this is capable of forming a multilayer structure of the ferroelectric thin film 120 and the contact layer 130. Accordingly, this manufacturing method is advantageous from the viewpoint of the manufacturing cost and the manufacturing time.

Next, description will be made regarding a sample (which will also be referred to as a “diode sample”) of an actually manufactured semiconductor apparatus 100B and evaluation thereof.

The size of each layer of the diode sample thus manufactured is as follows.
Ferroelectric thin film 120: 10 nm
Contact layer 130: 20 nm

Furthermore, the upper electrode 140 is designed to be 50×50 μm².

Description will be made below regarding the formation conditions for each layer.

The substrate cleaning shown in FIG. 5A was performed in two cycles of SPM and DHF.

The ferroelectric thin film 120 and the contact layer 130 shown in FIGS. 5B and 5C were each deposited by ECR sputtering at room temperature. The HfNₓ in the ferroelectric thin film 120 was deposited in an Ar/N₂=(8/8 sccm) atmosphere with microwave electric power of 500 W and RF (high-frequency) electric power of 400 W. The HfN_{y} in the contact layer 130 was deposited in an Ar/N₂=(10/0.2 sccm) atmosphere with microwave electric power of 500 W and RF (high-frequency) electric power of 400 W.

The heat treatment shown in FIG. 5D was applied to each sample using PMA or PDA. PMA or PDA were applied to each sample in a N₂ (1 SLM) atmosphere at 400° C. for 5 minutes or at 500° C. for 5 minutes.

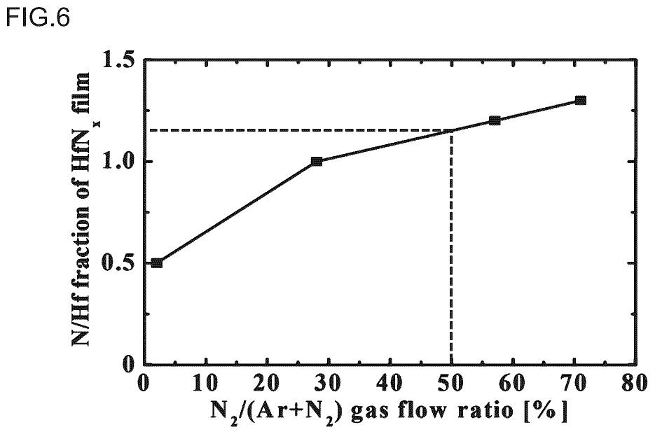

FIG. 6 shows the relation between the gas flow ratio in deposition of HfNₓ and the composition ratio of Hf and N. As described above, in a case in which the ferroelectric thin film 120 of HfNₓ is formed in an Ar/N₂ (=8/8 sccm) atmosphere, N₂/(Ar+N₂)=50% holds true. Accordingly, the composition ratio x is estimated to be 1.15. On the other hand, in a case in which the contact layer 130 of HfN_{y} is formed in an Ar/N₂ (=10/0.2 sccm) atmosphere, N₂/(Ar+N₂)=2% holds true. Accordingly, the composition ratio y is estimated to be 0.5. It should be noted that the relation shown in FIG. 6 includes error. Accordingly, the composition ratios x and y each include error, which is estimated to be on the order of 20% at maximum. Accordingly, the composition ratio x in an actual crystal is in a range of at least 0.9≤x≤1.4. In contrast, the composition ratio y is in a range of 0.4≤y≤0.6.

Description will be made below regarding the evaluation results of a diode sample manufactured under the conditions described above.

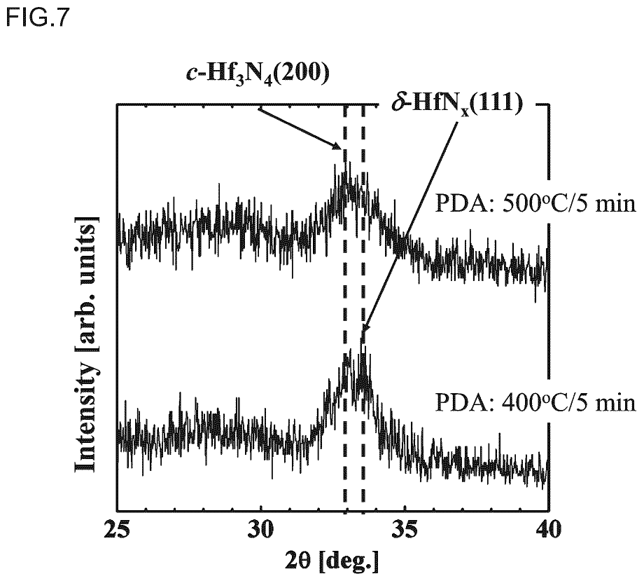

FIG. 7 is a diagram showing the measurement results of the manufactured sample using the X-ray diffraction (XRD) method. FIG. 7 shows the measurement results of a sample subjected to PDA processing in a condition of 500° C./5 minutes and the measurement results of a sample subjected to PDA processing in a condition of 400° C./5 minutes. The measurement was performed before the formation of an electrode after the heat treatment shown in FIG. 5D.

It can be understood that all the samples were formed in a mixed form of both the c-Hf₃N₄(200) crystal structure and the c-HfNₓ (111) crystal structure. However, it can be understood that, in a case in which the sample is formed in a condition of 400° C./5 minutes, the δ-HfNₓ (111) crystal structure is a dominant component, and such a sample has a rhombohedral crystal structure.

That is to say, it can be understood that, from among the deposition conditions for the samples that were measured in this measurement, the sample formed by heat treatment in a condition of 400° C./5 minutes can effectively provide a rhombohedral crystal structure. Description will be made regarding the evaluation results of the electrical characteristics and magnetic characteristics of a HfN_{1.15} thin film sample (which will be referred to as a “MFS diode sample” hereafter) manufactured in the conditions described above.

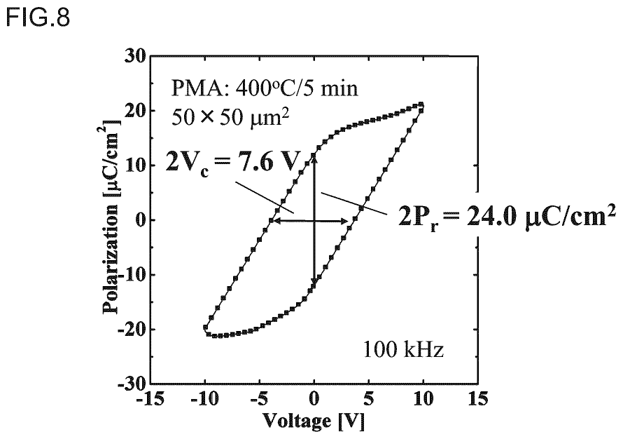

FIG. 8 is a diagram showing the P-V (polarization-voltage) characteristics of the MFS diode sample. The horizontal axis shows the applied voltage, and the vertical axis shows the polarization. It can be understood based on the results that the HfNₓ thin film having a rhombohedral crystal structure has ferroelectricity. This is a new finding that has not been known conventionally.

Furthermore, anti-voltage 2V_{C}, i.e., the voltage hysteresis width, was 7.6 V, and the residual polarization 2Pᵣ was 24.0 μC/cm². This is dramatically larger than the conventionally reported residual polarization 2Pᵣ of HfO₂ of 2.5 μC/cm² with no other elements added (Non-patent document 6). One of the reasons why such a large residual polarization is provided is that the displacement of nitrogen (N) atoms due to the electric field is larger than that of oxygen atoms.

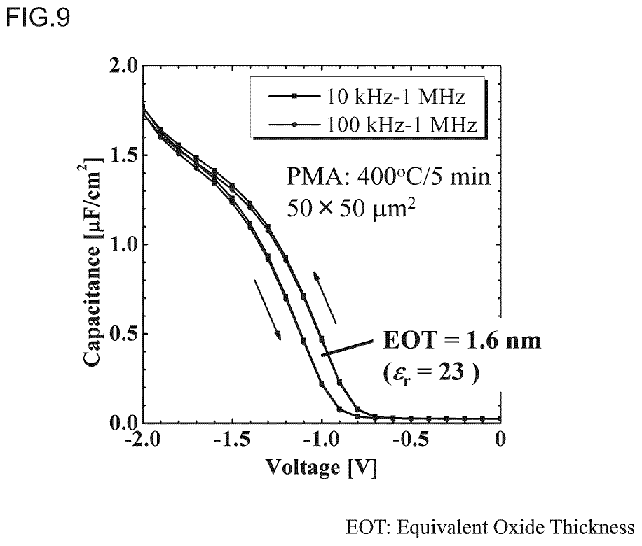

FIG. 9 is a diagram showing the C-V (capacitance-voltage) characteristics of the MFS diode sample. The relative dielectric constant εᵣ of the HfNₓ that exhibits ferroelectricity described in the present embodiment is estimated to be 23. Amorphous HfNₓ configured as an insulating material having a high dielectric constant has a relative dielectric constant εᵣ on the order of 14 to 18 (Non-patent document 4). It can be understood that the MFS diode sample exhibits a relative dielectric constant that is higher than that of the amorphous HfNₓ.

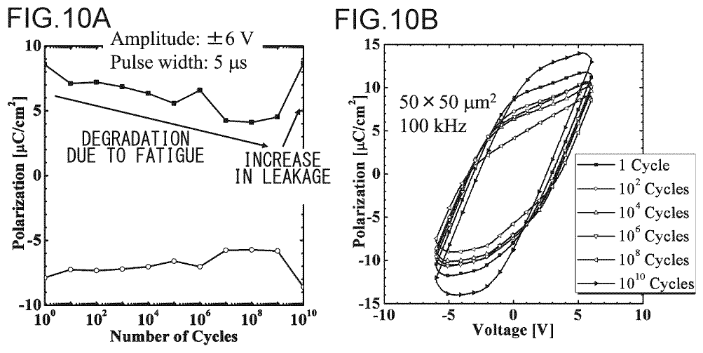

FIGS. 10A and 10B are diagrams each showing the measurement results of the fatigue characteristics of the MFS diode sample. FIG. 10A shows the occurrence of characteristics degradation accompanying an increase in leakage after the number of switching cycles exceeds 10¹⁰. However, it can be understood that the MFS diode sample is tolerant of 10⁹ switching cycles, which is sufficient for practical use. Furthermore, as shown in FIG. 10B, no imprinting phenomenon is observed.

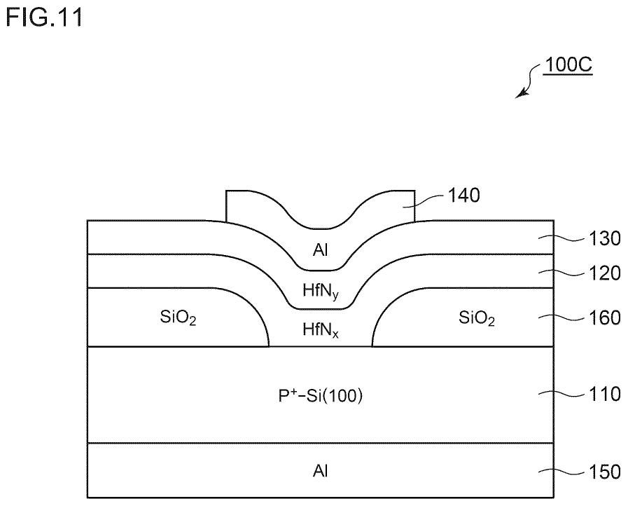

FIG. 11 is a cross-sectional diagram of a semiconductor apparatus 100C according to an embodiment. The semiconductor apparatus 100C is configured as a MFS diode as with an arrangement shown in FIG. 4. The semiconductor apparatus 100C includes a SiO₂ layer in addition to the MFS diode shown in FIG. 4. When the region in which the metal electrode 140 is formed is an active region of the diode, the SiO₂ layer is formed in a region outside the active region. That is to say, in the active region, the SiO₂ layer 150 is not formed as an interface between the ferroelectric thin film 120 and the Si substrate 110. Accordingly, the effect of a depolarizing electric field due to the SiO₂ layer 160 does not become a problem.

With such an arrangement provided with the SiO₂ layer 160, this is capable of reducing leakage from the side face of the ferroelectric thin film 120 of the diode to the Si substrate 110, thereby allowing the characteristics to be further improved.

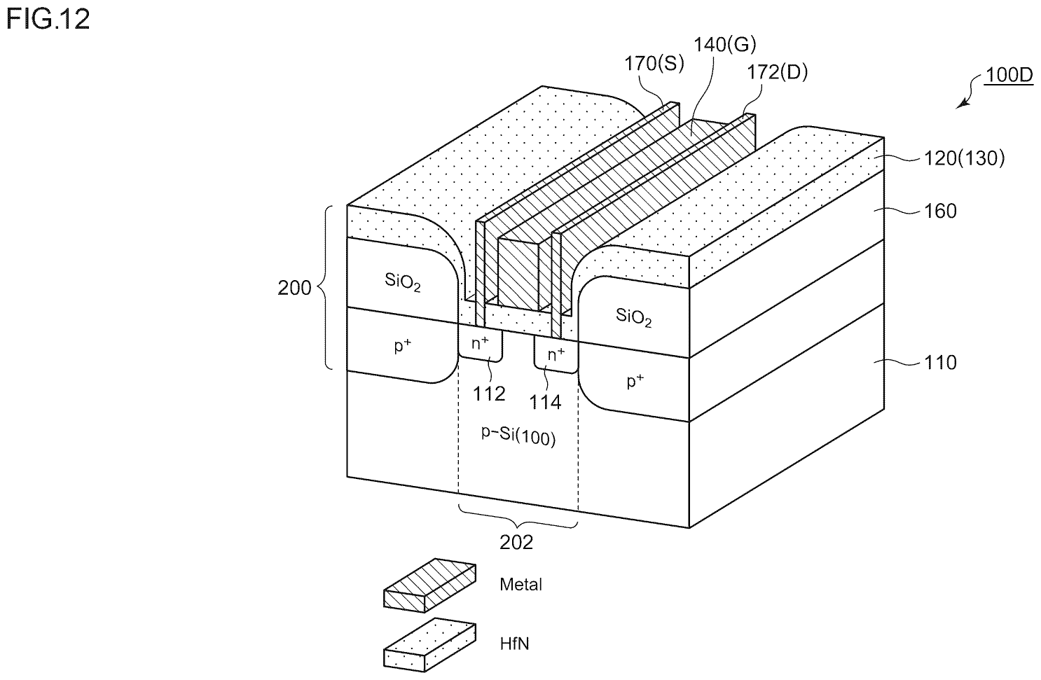

FIG. 12 is a cross-sectional diagram of a semiconductor apparatus 100D according to an embodiment. The semiconductor apparatus 100D includes the MFS transistor 200.

The transistor 200 is formed on the Si substrate 110. The ferroelectric thin film 120 is configured as a gate insulating film formed in the gate region of the Si substrate 110. The ferroelectric thin film 120 includes HfNₓ (1<x) having a rhombohedral crystal structure.

In the present embodiment, the SiO₂ layer 160 is formed on the Si substrate 110 such that it surrounds the active region 202 including the drain (D), gate (G), and source (S).

The n⁺ layers 112 and 114 are formed in the source region and the drain region of the Si substrate 110, respectively. The contact layer 130 is formed on the ferroelectric thin film 120. However, the boundary between the ferroelectric thin film 120 and the contact layer 130 is not shown in FIG. 11. Instead, the ferroelectric thin film 120 and the contact layer 130 are shown as a single layer.

In the gate region (G), the metal electrode 140, which is configured as the gate electrode, is formed on the ferroelectric thin film 120 (contact layer 130). Furthermore, a source electrode 170 and a drain electrode 172 are formed such that they are drawn from the n⁺ layers 112 and 114.

The above is the configuration of the semiconductor apparatus 100D. It should be noted that, in a case in which the MFS transistor 200 is formed as shown in FIG. 11, the formation of the SiO₂ layer 160 may be omitted.

### Usage

The MFS device described above may be employed as a nonvolatile memory cell using the change in capacitance or the change in the threshold voltage.

The usage of the MFS device is not restricted to such nonvolatile memory (digital storage element). Also, the MFS device can be employed as an analog storage element using the continuous change in capacitance or threshold value according to the gate voltage. Also, the MFS device can be employed as a D/A converter. Also, such a floating gate device may be employed as a neural calculation element employed in a neural network. It can be anticipated that such a MFS device can be applied to neurodevices and the like that emulate the human brain, which provide weighted calculation of input signals.

The above-described embodiments show only an aspect of the mechanisms and applications of the present invention. Rather, various modifications and various changes in the layout can be made without departing from the spirit and scope of the present invention defined in appended claims.

Description has been made regarding the present invention with reference to the embodiments using specific terms. However, the above-described embodiments show only an aspect of the mechanisms and applications of the present invention. Rather, various modifications and various changes in the layout can be made without departing from the spirit and scope of the present invention defined in appended claims.

What is claimed is:

1. A semiconductor apparatus comprising:
a Si substrate; and
a ferroelectric thin film formed on the Si substrate and including HfNₓ (1<x) having a rhombohedral crystal structure.

2. The semiconductor apparatus according to claim 1, wherein 1.1≤x≤1.3 holds true.

3. The semiconductor apparatus according to claim 1, wherein 1.15≤x≤1.2 holds true.

4. The semiconductor apparatus according to claim 1, further comprising an SiO₂ layer formed outside an active region in which the semiconductor device is formed.

5. The semiconductor apparatus according to claim 1, comprising:
a contact layer including HfN_{y} (y<1) formed on the ferroelectric thin film; and
a metal electrode formed on the contact layer.

6. The semiconductor apparatus according to claim 1, wherein the ferroelectric thin film has a thickness of 3 nm to 20 nm.

7. A forming method for a ferroelectric thin film, comprising:
forming a HfNₓ (1<x) layer by depositing Hf on a Si substrate using an Electron Cyclotron Resonance (ECR) sputtering method in a gas atmosphere including N₂ and Ar;
crystalizing the HfNₓ layer into a rhombohedral crystal structure by subjecting it to heat treatment after it is formed.

8. A semiconductor apparatus comprising a transistor, wherein the transistor comprises:
a Si substrate;
a ferroelectric thin film formed in a gate region on the Si substrate, and including HfNₓ (1<x) having a rhombohedral crystal structure; and
n⁺ layers formed in a drain region and a source region each adjacent to the gate region on the Si substrate.

9. The semiconductor apparatus according to claim 8, wherein 1.1≤x≤1.3 holds true.

10. The semiconductor apparatus according to claim 8, wherein 1.15≤x≤1.2 holds true.

11. The semiconductor apparatus according to claim 8, further comprising a SiO₂ layer formed on the Si substrate such that it is formed outside an active region including the gate region, the source region, and the drain region.
